(19) United States
(12) Patent Application Publication
(10) Pub. No.: US 2009/0194890 A1
(43) Pub. Date: Aug. 6, 2009

(54) Integrated Circuit and Memory Module

(76) Inventors: Knut Kahlisch, Dresden (DE); Martin Reiss, Dresden (DE); Joerg Keller, Dresden (DE)

Correspondence Address: SLATER & MATSIL, L.L.P., 17950 PRESTON ROAD, SUITE 1000, DALLAS, TX, 75252, US

(21) Appl. No.: 12/023,557

(22) Filed: Jan. 31, 2008

(51) Int. Cl. H01L 23/28

(52) U.S. Cl. 257/787; 257/E23.116

(57) ABSTRACT

Embodiments of the invention relate generally to an integrated circuit and a memory module. In an embodiment of the invention, an integrated circuit is provided. The integrated circuit may include a semiconductor carrier including at least one electrically inactive region on an upper surface thereof, a passivation layer structure disposed above the upper surface of the semiconductor carrier, and at least one lithographic trench in the passivation layer structure above the at least one electrically inactive region on the upper surface of the semiconductor carrier.

### TECHNICAL FIELD

Embodiments of the invention relate generally to an integrated circuit and a memory module.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A shows a top view of an integrated circuit according to an embodiment of the invention;

FIG. 1B shows a cross-section along line A-A in FIG. 1A;

FIG. 2 shows a top view of an integrated circuit according to another embodiment of the invention;

FIG. 3 shows a top view of an integrated circuit according to yet another embodiment of the invention;

FIG. 4 shows a top view of an integrated circuit according to yet another embodiment of the invention;

FIG. 5 shows a top view of an integrated circuit according to yet another embodiment of the invention;

FIG. 6 shows a top view of an integrated circuit according to yet another embodiment of the invention;

FIG. 7 shows a top view of an integrated circuit according to yet another embodiment of the invention;

FIG. 8A shows a top view of an integrated circuit according to yet another embodiment of the invention;

FIG. 8B shows a cross-section along line A-A in FIG. 8A;

FIG. 9 shows a top view of an integrated circuit according to yet another embodiment of the invention;

FIG. 10 shows a top view of an integrated circuit according to yet another embodiment of the invention;

FIG. 11 shows a top view of an integrated circuit according to yet another embodiment of the invention;

FIGS. 12A and 12B show a memory module (FIG. 12A) and a stackable memory module (FIG. 12B) in accordance with an embodiment of the invention;

FIG. 13 shows a sectional view of an integrated circuit according to yet another embodiment of the invention; and

FIG. 14 shows a sectional view of an integrated circuit according to yet another embodiment of the invention.

### DETAILED DESCRIPTION OF ILLUSTRATIVE EMBODIMENTS

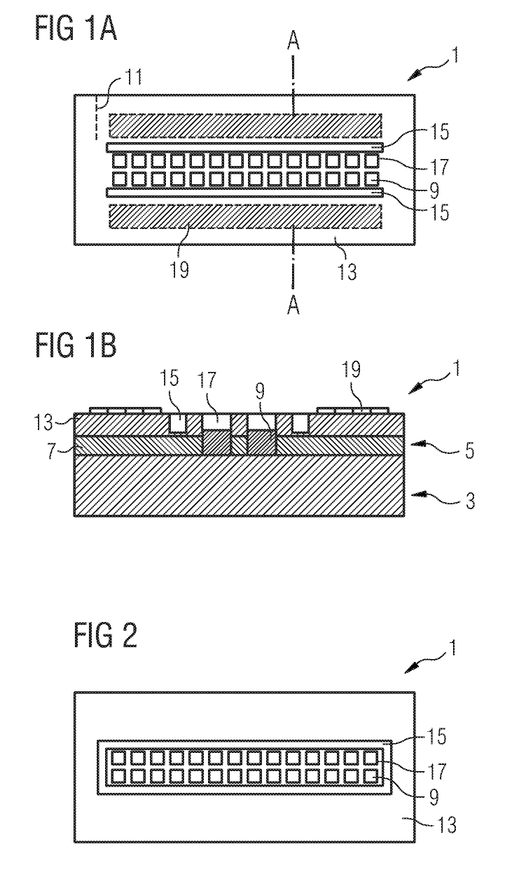

FIGS. 1A and 1B show an integrated circuit according to a first embodiment of the invention. The integrated circuit 1 may include a semiconductor carrier 3 (such as a semiconductor substrate or chip), the upper surface 5 of which has an electrically inactive region 7 and an electrically active region. In an embodiment of the invention, the substrate (e.g., a wafer substrate) 3 may be made of semiconductor materials of various types, including silicon, germanium, Group III to V or other types, including polymers, for example, although in another embodiment of the invention, other suitable materials can also be used. In an exemplary embodiment of the invention, the substrate 3 is made of silicon (doped or undoped), in an alternative embodiment of the invention, the substrate 3 is a silicon on insulator (SOI) wafer. As an alternative, any other suitable semiconductor materials can be used for the substrate 3, for example, semiconductor compound material such as gallium arsenide (GaAs), indium phosphide (InP), but also any suitable ternary semiconductor compound material or quaternary semiconductor compound material such as indium gallium arsenide (InGaAs). The electrically active region includes or is formed by a plurality of bond pads 9, e.g., made of Al, Au, Ag, Cu or Pt, and a plurality of fuses 11, e.g., made of Al (for clarity reasons only some of the fuses 11 are shown in FIG. 1A). By means of the fuses 11, additional cells, e.g., additional memory cells, of the semiconductor carrier 3 may be activated. The electrically inactive region 7 is, e.g., formed by a covering layer, e.g., made of silicon oxide or silicon nitride, covering and protecting the layers of the semiconductor carrier 3 arranged below the covering layer. In an embodiment of the invention, a passivation layer structure 13 is disposed on top of the upper surface 5 of the semiconductor carrier 3. The passivation layer structure 13 includes at least one passivation layer, for example, a first passivation layer, e.g., made of silicon nitride or polyimide, disposed on top of the upper surface 5 of the semiconductor carrier 3, and a second passivation layer, e.g., made of polyimide, disposed on top of the upper surface of the first passivation layer.

Two lithographic trenches 15 are formed in the passivation layer structure 13 above the electrically inactive region 7. In the embodiment shown in FIGS. 1A and 1B, the lithographic trenches 15 are formed as blind trenches, that is, the lithographic trenches 15 do not completely but only partially extend throughout the passivation layer structure 13. In other words, the height/depth of the lithographic trenches 15 is lower than the height/thickness of the passivation layer structure 13. However, in an alternative embodiment, the lithographic trenches 15 may completely extend throughout the passivation layer structure 13 until (or slightly into) the covering layer.

Further, a plurality of contact trenches 17 may be formed in the passivation layer structure 13 so as to expose the plurality of bond pads 9. The cross section of the contact trenches 17 basically corresponds to the cross section of the bond pads 9. Via the contact trenches 17, the bond pads 9 can be electrically contacted with an electrically conductive contacting material, e.g., Al, Au, Cu or Pt (for example, in the form of a wire), disposed above and in electrical contact with the respective bond pad 9. Further, a plurality of fuse trenches is formed in the passivation layer structure 13, exposing the plurality of fuses 11.

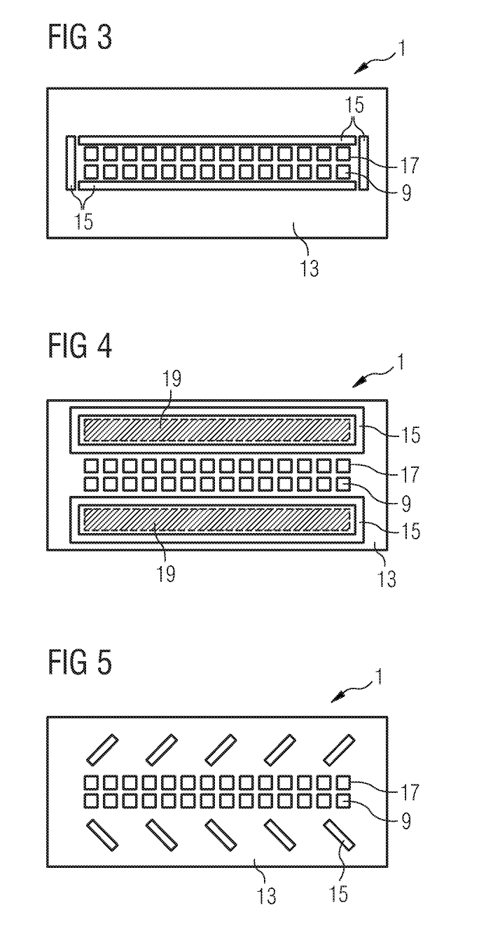

The two lithographic trenches 15 are formed in the passivation layer structure 13 so as to longitudinally surround the plurality of bond pads 9, that is, so as to longitudinally extend along the bond pads 9. In other words, the lithographic trenches 15 extend substantially in parallel to the longitudinal axis of the bond pad array. For example, the length of the lithographic trenches 15 may be in the range from about 500 μm to about 2 mm, e.g., in the range of about 750 μm to about 1.5 mm. By way of example, the depth/height of the lithographic trenches 15 may be in the range from about 4 μm to about 8 μm, e.g. in the range from about 5 μm to about 7 μm. Alternatively, as shown in FIG. 2, a single lithographic trench 15 may be provided in the passivation layer structure 13, which substantially completely surrounds the plurality of bond pads 9. Alternatively, as shown in FIG. 3, four lithographic trenches 15 may be formed in the passivation layer structure 13, two lithographic trenches 15 extending along the longitudinal sides of the bond pad array, and two lithographic trenches 15 extending along the front sides of the bond pad array. In general, an arbitrary number of lithographic trenches 15 may be provided in an alternative embodiment of the invention in accordance with the respective requirement.

As shown in FIG. 1A, an adhesive (or die attach material) 19 is applied to, e.g., printed to, a predetermined portion of the upper surface of the passivation layer structure 13, and a mold compound (not shown), e.g., an epoxy resin, forming a semiconductor carrier housing is disposed above the adhesive 19 and the upper surface of the passivation layer structure 13. For example, the mold compound can be formed in a molding process, for example, in a transfer molding process. The adhesive 19 may be any material being suitable to enhance adhesion between the passivation layer structure 13 and the mold compound.

The at least one lithographic trench 15 shown in FIGS. 1 to 3 at least partially surrounds the bond pad array and is closely positioned thereto so as to provide a flow barrier for the adhesive 19 which protects the bond pads 9 from being contaminated by the adhesive 19. In other words, the at least one lithographic trench 15 is located between the bond pad array and a region where the adhesive 19 is applied to the passivation layer structure 13. In other words, the at least one lithographic trench 15 allows for controlling the flow behavior of the adhesive 19. In addition, the at least one lithographic trench 15 increases the surface area being available for adhesion between the passivation layer structure 13 and the adhesive/mold compound 19. Thus, after application of the adhesive 19 and formation of the mold compound, the at least one lithographic trench 15 will be at least partially filled with at least one of the mold compound and the adhesive 19.

FIG. 4 shows an integrated circuit according to another embodiment of the invention. According to this embodiment of the invention, the at least one lithographic trench 15 is shaped so as to completely surround, that is, so as to restrict, the upper surface region of the passivation layer structure 13 to which the adhesive 19 is applied to.

FIG. 5 shows an integrated circuit according to yet another embodiment of the invention. According to this embodiment of the invention, a plurality of lithographic trenches 15 is formed in the passivation layer structure 13 within the areas/regions where the adhesive 19 is applied to the passivation layer structure 13 (see FIGS. 1A and 4). This has the effect that the flow behavior of the adhesive can be controlled/adjusted and that the surface area available for adhesion between the passivation layer structure 13 and the adhesive/mold compound 19 can be increased. By appropriately controlling the flow behavior of the adhesive, adhesion between the adhesive 19 and the passivation layer structure 13 may be increased, and the enclosure of air and formation of voids can be prevented. Further, the lithographic trenches 15 can act as a barrier/anchorage regarding movement of the semiconductor carrier housing formed by the mold compound relative to the passivation layer structure 13/semiconductor carrier 3.

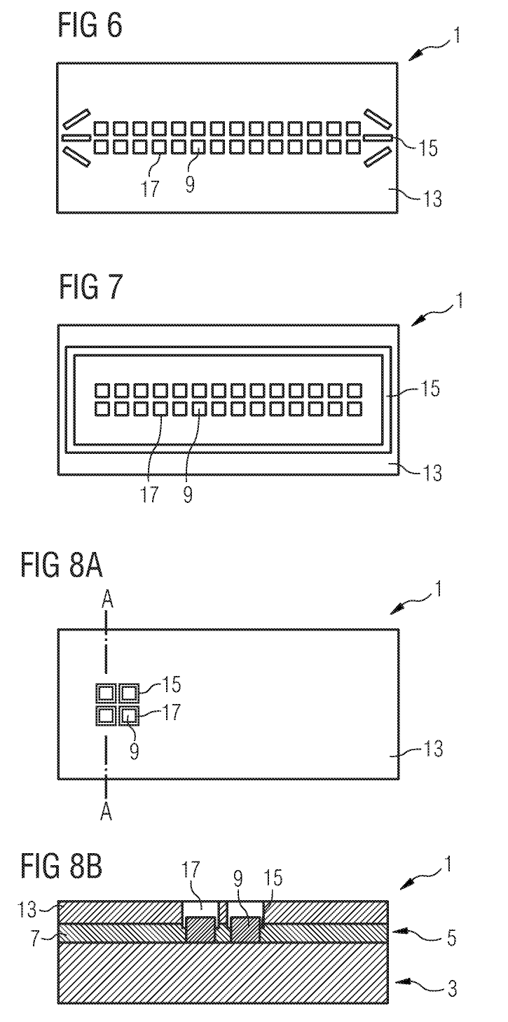

FIG. 6 shows an integrated circuit according to yet another embodiment of the invention. According to this embodiment of the invention, a plurality of lithographic trenches 15 is formed in the passivation layer structure 13 at the front sides of the bond pad array. This has the effect that the surface area available for adhesion between the passivation layer structure 13 the mold compound can be increased. Furthermore, the flow behavior of the mold compound can be affected, that is, the flow behavior of the mold compound may be adjusted via the lithographic trenches 15 so that adhesion between the mold compound and the passivation layer structure 13 can be increased and the formation of voids can be prevented. For example, the one or more lithographic trenches 15 can be formed in a critical packaging area, that is, in an area/region where problems in the adhesion of the passivation layer structure 13 and the mold compound occur.

FIG. 7 shows an integrated circuit according to yet another embodiment of the invention. According to this embodiment of the invention, a single rectangular lithographic trench 15 is formed in the passivation layer structure 13 so as to extend through both an area where adhesive 19 is applied to the passivation layer structure 13 and an area where adhesion problems between the mold compound and the passivation layer structure 13 have been observed. Thus, with this passivation layer structure design both the effects as stated with regard to the embodiment shown in FIG. 5 and the effects as stated with regard to the embodiment shown in FIG. 6 can be achieved. The lithographic trench 15 is not limited to a rectangular trench but instead can have an oval shape, for example.

In a similar way, the effects as stated with regard to the embodiment shown in FIG. 1 and the effects as stated with regard to the embodiment shown in FIG. 6 may be achieved/combined with a passivation layer structure comprising a single lithographic trench, for example, having a rectangular or oval shape, extending both through a critical packaging area and between the bond pad array and the area where the adhesive 19 is applied to.

FIGS. 8A and 8B show an integrated circuit according to yet another embodiment of the invention. According to this embodiment of the invention, a lithographic trench 15 is respectively formed around at least one contact trench 17 (e.g. around each contact trench 17) so as to be adjacent thereto. In other words, the contact trench 17 is widened/enlarged by means of the lithographic trench 15. According to this embodiment, the shape of the lithographic trench 15 basically corresponds to the shape of the contact trench 17. For example, as shown in FIG. 8A, both the contact trench 17 and the lithographic trench 15 may have a rectangular shape such as a square shape, with a side length of the contact trench 17 being smaller than that of the lithographic trench 15. As can be seen in FIG. 8B, by means of the lithographic trench 15 the bond pad 9 is at least partially exposed on a circumferential side thereof. That is, according to this embodiment, the depth/height of the lithographic trench 15 is greater than that of the contact trench 17. After formation of the contact trench 17 and the lithographic trench 15, the bond pad 9 is contacted with an electrically conductive contacting material such as a wire, and mold compound is applied onto the passivation layer structure 13 and, thus, also into the contact trench 17 and the lithographic trench 15. With the passivation layer structure design according to this embodiment of the invention an effect on a mechanical stability of the connection between the electrically conductive contacting material and the electrically conductive contact can be achieved. This is because each of the electrically conductive contacting material, the electrically conductive contact and the connection portion formed therebetween is surrounded by/embedded in the same material, namely by/in the mold compound (compare FIGS. 1B and 8B). That is, this embodiment provides a uniform and stable environment for and thus protection of the connection portion between the electrically conductive contacting material and the electrically conductive contact so that disengagement of the electrically conductive contacting material and the electrically conductive contact can be prevented. Furthermore, the surface area available for adhesion between the passivation layer structure 13 and the mold compound can be increased. Further, the flow behavior of the mold compound can be affected/adjusted.

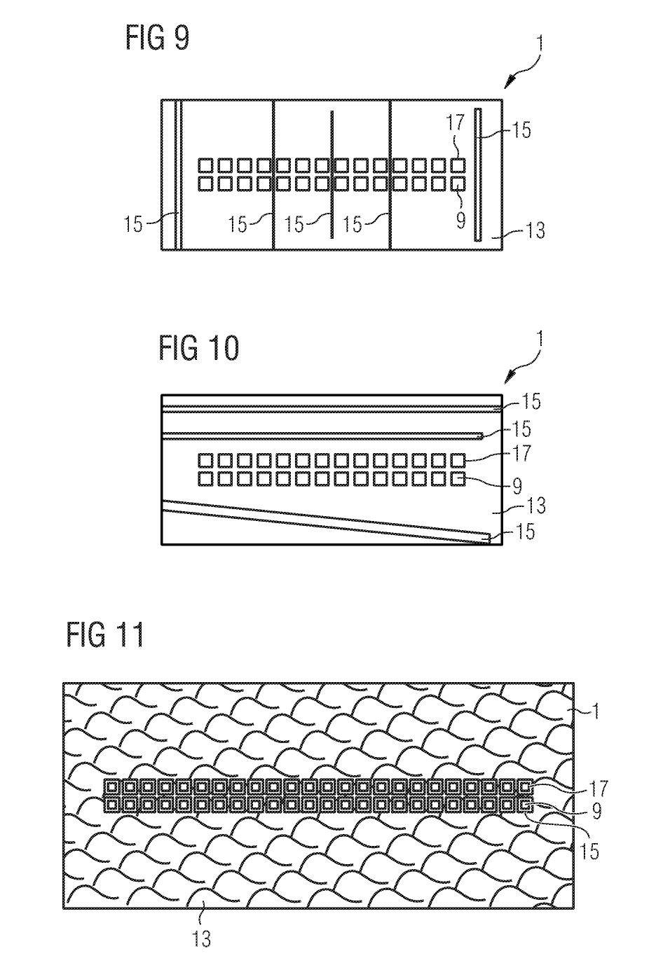

FIG. 9 shows an integrated circuit according to yet another embodiment of the invention. According to this embodiment of the invention, at least one lithographic trench 15 is formed in the passivation layer structure 13 so as to have an effect on the warpage behavior of the integrated circuit 1. For example, such a passivation layer structure design may be used to compensate for the different thermal expansion behavior of the materials of the integrated circuit 1. To this end, for example, the passivation layer 13 can be divided into several segments, for example, as shown in FIG. 9, by means of a plurality of lithographic trenches 15 formed in the passivation layer structure 13 so as to basically extend along the cross direction of the semiconductor carrier 3. Alternatively or additionally, as can be seen in FIG. 10, the passivation layer structure 13 may be divided into two or more segments by means of one or more lithographic trenches 15 basically extending along the longitudinal direction of the semiconductor carrier 3 and/or by means of one or more inclined lithographic trenches 15.

For example, two or more of the embodiments shown throughout FIGS. 1 to 10 may be combined with each other, that is, two or more of the different passivation layer structure designs (configuration of the at least one lithographic trench 15 in the passivation layer structure 13) shown in FIGS. 1 to 10 may be combined with each other so as to yield a single passivation layer structure design providing the effects of the different combined passivation layer structure designs.

For example, the respective passivation layer structure design may be optimized using a simulation process/program, such as FEM simulation. In an embodiment of the invention, the layout and the design of the masks for patterning the passivation layer structure, e.g., may be used to achieve various technical effects, e.g., the warpage of the carrier, the flow behavior of the mold compound and all the other characteristics mentioned in the various embodiments of the invention. Thus, a very simple mechanism is provided in accordance with an embodiment of the invention to design the passivation layer structure in order to achieve various technical effects. These additional trench structures are provided on or above an inactive region of the upper surface of the carrier, that e.g., on or above a region which cannot be electrically connected to electrical components of the semiconductor carrier such as driver components, switches, memory cells and so on.

Each of the embodiments shown throughout FIGS. 1 to 10 may be manufactured by forming/depositing the passivation layer structure 13 above the upper surface 5 of the semiconductor carrier 3, forming the at least one lithographic trench 15 in the passivation layer structure 13 above the electrically inactive upper surface region 7 of the semiconductor carrier 3, and forming the plurality of contact trenches 17 (and fuse trenches) in the passivation layer structure 13, thereby exposing the plurality of bond pads 9 (and fuses 11).

In an embodiment of the invention, the at least one lithographic trench 15 is formed in the passivation layer structure 13 by a lithographic process. For example, a photoresist may be deposited on the upper surface of the passivation layer structure 13, exposed to light using a mask, and developed. Using the developed photoresist, the at least one lithographic trench 15 can be formed in the passivation layer structure 13 by means of etching, e.g., by means of wet etching or by means of dry etching. For example, developing of the photoresist and etching of the lithographic trench 15 may be performed in a single process step. However, provided that the passivation layer structure 13 or at least an upper layer thereof is made of a photosensitive material, the lithographic trench 15 may be formed in the passivation layer structure 13 by exposing the upper surface of the passivation layer structure 13 to light using a mask, and by developing the passivation layer structure 13.

For example, the at least one lithographic trench 15 and the plurality of contact trenches 17 can be formed in a common process, that is, the at least one lithographic trench 15 may be formed during the formation of the plurality of contact trenches 17, that is, during the “bond pad opening” process. For example, the at least one lithographic trench 15 and the plurality of contact trenches 17 may be formed by means of a common lithographic process using a common mask defining the patterning structure of the at least one lithographic trench 15 and the contact trenches 17, followed by a common etching process.

FIG. 11 shows an integrated circuit according to yet another embodiment of the invention. According to this embodiment of the invention, at least a portion of the upper surface of the passivation layer structure 13 is roughened in order to increase the surface being available for adhesion of the mold compound/adhesive 19 and the passivation layer structure 13. For example, the roughening of at least a portion of the upper surface of the passivation layer structure 13 may be performed after the bond pad opening, that is, after formation of the contact trenches 17 in the passivation layer structure 13. This has the effect that the roughened surface is not exposed to the bond pad opening process, thereby protecting the roughened surface from being destroyed by chemicals used in the bond pad opening process. In order not to damage the bond pads 9, the upper surface of the passivation layer structure 13 is selectively roughened with regard to the exposed/opened bond pads 9. For example, the upper surface of the passivation layer structure 13 may be selectively etched, for example, wet-etched, or mechanically roughened selective to the bond pads 9, for example, using a grinding tape. For example, one or more of the embodiments shown throughout FIGS. 1 to 10 may be combined with the embodiment shown in FIG. 11. For example, as shown in FIG. 11, the bond pad protection as shown in FIGS. 8A and 8B may be combined with the selectively roughened surface of the passivation layer structure 13 as shown in FIG. 11

In an embodiment of the invention, an integrated circuit may include a semiconductor carrier having at least one electrically inactive region on an upper surface thereof, a passivation layer structure disposed above the upper surface of the semiconductor carrier, and at least one lithographic trench in the passivation layer structure above the at least one electrically inactive region on/of the upper surface of the semiconductor carrier. For example, the semiconductor carrier may be a semiconductor chip or a semiconductor substrate. The at least one electrically inactive upper surface region of the semiconductor carrier is an upper surface region which does not provide access to or which is not intended/provided for accessing the circuit of the integrated circuit. In other words, the at least one electrically inactive upper surface region does not include any element which is provided/used for accessing the circuit, such as a bond pad or a fuse. By way of example, the at least one electrically inactive upper surface region of the semiconductor carrier may be an upper surface region being electrically insulated from the circuit of the integrated circuit. For example, the at least one electrically inactive upper surface region may include or consist of an electrically insulating material such as a dielectric material, e.g., silicon oxide, or a semiconductor carrier covering material, e.g., silicon nitride.

For example, the semiconductor carrier can further include at least one electrically active region on the upper surface thereof in addition to the at least one electrically inactive upper surface region. In this case, the integrated circuit may further include at least one further trench in the passivation layer structure exposing the at least one electrically active region. Contrary to the at least one electrically inactive upper surface region of the semiconductor carrier, the at least one electrically active upper surface region may provide an access to and is used or at least intended for accessing the circuit of the integrated circuit. That is, the at least one electrically active upper surface region of the semiconductor carrier is in electrical contact with and/or a part of the integrated circuit. For example, the at least one electrically active region of the upper surface of the semiconductor carrier can comprise or consist of an electrically conductive material. For example, the at least one electrically active region on the upper surface of the semiconductor carrier may include or consist of at least one of an electrically conductive contact, such as a bond pad, and a fuse respectively formed on the upper surface of the semiconductor carrier. For example, the further trench can be one of a contact trench and a fuse trench exposing the electrically conductive contact and the fuse, respectively. For example, electrically conductive contacting material, e.g., in the form of a wire, can be disposed above and in electrical contact with the electrically conductive contact, that is, within the contact trench.

For example, the at least one lithographic trench in the passivation layer structure may form a blind hole/blind trench in the passivation layer structure. However, alternatively, the at least one lithographic trench in the passivation layer structure may also completely extend throughout the passivation layer structure until (or slightly into) the upper surface of the semiconductor carrier. For example, the passivation layer structure may include or consist of a first passivation layer disposed above the upper surface of the semiconductor carrier and a second passivation layer disposed above the first passivation layer. In this case, for example, the at least one lithographic trench in the passivation layer structure may form a blind hole/blind trench in the first passivation layer or in the second passivation layer. However, the at least one lithographic trench in the passivation layer structure may also completely extend throughout the first passivation layer until the upper surface of the second passivation layer, or completely throughout both the first and the second passivation layer until the upper surface of the semiconductor carrier.

In an embodiment of the invention, the at least one lithographic trench is formed within the passivation layer structure by a lithographic process. For example, the at least one lithographic trench can be formed in the passivation layer structure by depositing a photoresist on the upper surface of the passivation layer structure, by exposing the photoresist to light using a mask, by developing the photoresist, and by etching the at least one lithographic trench using the developed photoresist. However, alternatively, provided that at least an upper layer or region of the passivation layer structure is made of a photosensitive/photostructurable material, the at least one lithographic trench may be formed in the passivation layer structure by exposing the passivation layer structure to light using a mask, and by developing the passivation layer structure. Thus, the at least one lithographic trench may also be called a lithographically formed trench, or lithographically etched trench.

For example, also the at least one further trench in the passivation layer structure exposing the at least one electrically active region can be formed by a lithographic process. For example, the at least one lithographic trench and the at least one further trench can be formed in a common process, that is, the at least one lithographic trench may be formed during the formation of the at least one further trench. For example, the at least one lithographic trench and the at least one further trench may be formed by a common lithographic process using a common mask defining the patterning structure of the at least one lithographic trench and the at least one further trench.

For example, the integrated circuit may further include an adhesive formed on at least a portion of the upper surface of the passivation layer structure. For example, the integrated circuit may further include a mold compound disposed above the adhesive and forming a semiconductor carrier housing. However, alternatively, the mold compound may be disposed directly on the upper surface of the passivation layer structure, that is, without an adhesive being provided between the upper surface of the passivation layer structure and the mold compound.

An effect of the integrated circuit according to an embodiment of the invention may be seen in that by appropriately configuring/shaping the at least one lithographic trench in the passivation layer structure, an effect on at least one of the following can be achieved:
the adhesion between the mold compound and the passivation layer structure (thus, it may be sufficient to provide the mold compound directly on the passivation layer structure, thereby saving the adhesive);
the adhesion between the adhesive and the passivation layer structure;
the warpage behavior of the semiconductor carrier and, thus, the integrated circuit;
the mechanical stability of the connection between the electrically conductive contacting material and the electrically conductive contact;
the flow behavior of the adhesive; and
the flow behavior of the mold compound.

Another effect of the integrated circuit according to various embodiments of the invention may be seen in that the at least one lithographic trench in the passivation layer structure and, thus, the integrated circuit can be manufactured in an easy, cheap and reliable manner. That is, the above effects can be achieved easily and cheaply. This is because the at least one lithographic trench in the passivation layer structure and the at least one further trench in the passivation layer structure exposing the at least one electrically active upper surface region of the semiconductor carrier can be formed in at least one common process, for example, by using a common mask defining the patterning structure of both the at least one lithographic trench and the at least one further trench exposing the at least one electrically active upper surface region. In this respect, for example, a conventional mask for forming the one or more contact trenches (and the one or more fuse trenches) may be revised so as to additionally define the patterning structure of the at least one lithographic trench.

According to another embodiment of the invention, an integrated circuit may include a semiconductor carrier having at least one electrically active region on an upper surface thereof, a passivation layer structure disposed above the upper surface of the semiconductor carrier, and at least one trench in the passivation layer structure exposing the at least one electrically active region on the upper surface of the semiconductor carrier, wherein at least a portion of an upper surface of the passivation layer structure is selectively roughened with regard to the at least one exposed electrically active region. As described above, the at least one electrically active upper surface region provides an access to and is intended for accessing a circuit of the integrated circuit. That is, the at least one electrically active upper surface region of the semiconductor carrier is in electrical contact with and/or a part of the circuit of the integrated circuit. For example, the at least one electrically active region of the upper surface of the semiconductor carrier can comprise or consist of an electrically conductive material. For example, the at least one electrically active region on the upper surface of the semiconductor carrier can comprise or consist of at least one of an electrically conductive contact, such as a bond pad, and a fuse respectively formed on the upper surface of the semiconductor carrier. For example, the trench can be one of a contact trench and a fuse trench exposing the electrically conductive contact and the fuse, respectively.

According to an embodiment, at least a portion of the upper surface of the passivation layer structure is selectively etched, for example, wet etched, with regard to the at least one exposed electrically active region.

According to another embodiment of the invention, at least a portion of the upper surface of the passivation layer structure is mechanically roughened selective to the at least one exposed electrically active region.

For example, the integrated circuit according to this embodiment of the invention may be manufactured by first forming the at least one trench in the passivation layer structure, and by then selectively roughening at least a portion of the upper surface of the passivation layer structure selective with regard to the at least one exposed electrically active region.

An effect of the integrated circuit according to this embodiment of the invention may be seen in that the roughened upper surface of the passivation layer structure provides an increased surface area for adhesion of the mold compound/adhesive on the passivation layer structure, wherein the at least one exposed electrically active region, such as a bond pad, is not roughened/damaged, that is, remains intact. That is, with the integrated circuit according to this aspect of the invention, adhesion between the mold compound/adhesive and the passivation layer structure may be enhanced in a reliable and safe manner, without risking damage of the at least one exposed electrically active region.

According to another embodiment of the invention, an integrated circuit may comprise a semiconductor carrier comprising an electrically conductive structure on an upper surface thereof, a passivation layer structure disposed above the upper surface of the semiconductor carrier, a trench in the passivation layer structure, a cover layer on the passivation layer structure, wherein a portion of the cover layer is placed into the trench, thereby providing a form closure between the portion of the cover layer placed into the trench and the passivation layer structure, wherein the trench is not exposing the electrically conductive structure on the semiconductor carrier. For example, the cover layer may be viscous during deposition so as to flow into the trench and is hardened after deposition on the passivation layer structure. For example, the trench may be a lithographic trench. For example, at least one further trench may be provided in the passivation layer structure exposing the electrically conductive structure on the upper surface of the semiconductor carrier. For example, the electrically conductive structure on the upper surface of the semiconductor carrier may comprise at least one of an electrically conductive contact and a fuse respectively formed on the upper surface of the semiconductor carrier. For example, the cover layer may comprise an adhesive material, wherein the cover layer is attached to the semiconductor carrier. For example, the cover layer may comprise a mold compound material, wherein the mold compound material is enclosing the integrated circuit. For example, the trench in the passivation layer structure may be configured such that it has an effect on the flow behavior of the adhesive material disposed on the upper surface of the passivation layer structure. Alternatively or additionally the trench in the passivation layer structure may be configured such that it has an effect on the flow behavior of the mold compound material disposed on the upper surface of the passivation layer structure. For example, the trench in the passivation layer structure may form a blind hole in the passivation layer structure. For example, the passivation layer structure may comprise a first passivation layer disposed above the upper surface of the semiconductor carrier and a second passivation layer disposed above the first passivation layer. For example, the trench in the passivation layer structure may form a blind hole in the first passivation layer or in the second passivation layer.

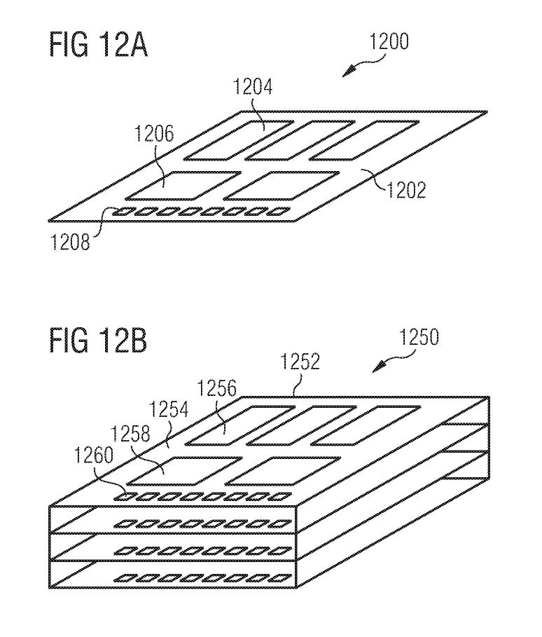

As shown in FIGS. 12A and 12B, in some embodiments, memory devices such as those described herein may be used in modules.

In FIG. 12A, a memory module 1200 is shown, on which one or more memory devices 1204 are arranged on a substrate 1202. The memory device 1204 may include numerous memory cells, each of which uses a memory element in accordance with an embodiment of the invention. The memory module 1200 may also include one or more electronic devices 1206, which may include memory, processing circuitry, control circuitry, addressing circuitry, bus interconnection circuitry, or other circuitry or electronic devices that may be combined on a module with a memory device, such as the memory device 1204. Additionally, the memory module 1200 includes multiple electrical connections 1208, which may be used to connect the memory module 1200 to other electronic components, including other modules.

As shown in FIG. 12B, in some embodiments, these modules may be stackable, to form a stack 1250. For example, a stackable memory module 1252 may contain one or more memory devices 1256, arranged on a stackable substrate 1254. The memory device 1256 contains memory cells that employ memory elements in accordance with an embodiment of the invention. The stackable memory module 1252 may also include one or more electronic devices 1258, which may include memory, processing circuitry, control circuitry, addressing circuitry, bus interconnection circuitry, or other circuitry or electronic devices that may be combined on a module with a memory device, such as the memory device 1256. Electrical connections 1260 are used to connect the stackable memory module 1252 with other modules in the stack 1250, or with other electronic devices. Other modules in the stack 1250 may include additional stackable memory modules, similar to the stackable memory module 1252 described above, or other types of stackable modules, such as stackable processing modules, control modules, communication modules, or other modules containing electronic components.

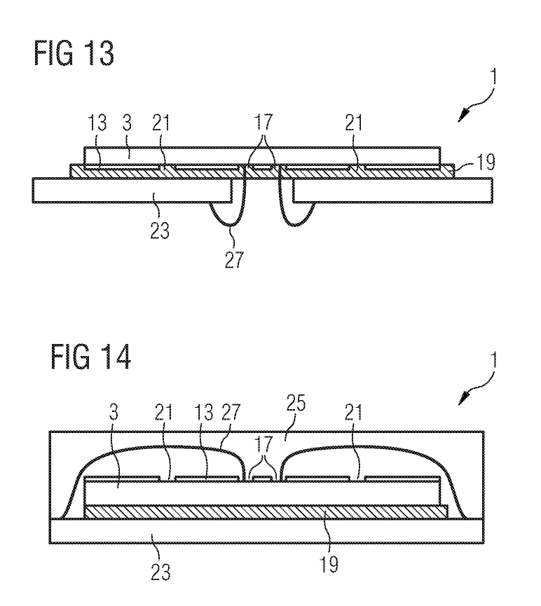

FIG. 13 shows an integrated circuit 1 according to a further embodiment of the invention. According to this embodiment of the invention, the integrated circuit 1 comprises a semiconductor carrier 3 comprising an electrically conductive structure on an upper surface thereof (the semiconductor carrier 3 being positioned upside down in FIG. 13). A passivation layer structure 13 is disposed on the upper surface of the semiconductor carrier 3. Trenches 21 are formed in the passivation layer structure 13. Trenches 21 are not exposing the electrically conductive structure on the upper surface of the semiconductor carrier 3, that is, the trenches 21 are formed above an electrically non-conductive structure/region of the upper surface of the semiconductor carrier 3. The trenches 21 may be formed as blind trenches or may completely extend through the passivation layer structure 13. For example, the trenches 21 may be etched into the passivation layer structure 13. The electrically conductive structure on the upper surface of the semiconductor carrier 3 may comprise bond pads (not shown) which are exposed by contact trenches 17 formed in the passivation layer structure 13. Via the contact trenches 17 the bond pads may be electrically contacted with an electrically conductive contacting material, e.g., in the form of a bond wire 27, to thereby electrically connect the semiconductor carrier 3 with a substrate 23. An adhesive layer 19 of viscous adhesive may be disposed on the passivation layer structure 13 so that a portion of the viscous adhesive flows into or is inserted/pressed into the trenches 21 (and the contact trenches 17), thereby providing a form closure between the portion of the adhesive layer 19 inserted into the trenches 21 (and the contact trenches 17) and the passivation layer structure 13/semiconductor carrier 3 after hardening of the adhesive.

FIG. 14 shows an integrated circuit 1 according to a further embodiment of the invention. According to this embodiment of the invention, the integrated circuit 1 comprises a semiconductor carrier 3 comprising an electrically conductive structure on an upper surface thereof. For example, the electrically conductive structure comprises one or more bond pads and/or one or more fuses. A passivation layer structure 13 is disposed above the upper surface of the semiconductor carrier 3. An adhesive layer 19 is disposed on the bottom surface of the semiconductor carrier 3. Via the adhesive layer 19 the semiconductor carrier 3 is fixed with its bottom surface to a substrate 23. Trenches 21 are formed in the passivation layer structure 13, the trenches 21 not exposing the electrically conductive structure on the upper surface of the semiconductor carrier 3. Further trenches, e.g., contact trenches 17, may be formed in the passivation layer 13, the further trenches respectively exposing a part of the electrically conductive structure such as a bond pad (not shown). By means of an electrically conductive wire material 27 the semiconductor carrier 3 can be electrically connected with the substrate 23 via the further trenches. Further, a mold compound material 25 may be provided above the semiconductor carrier 3 and the substrate 23 so as to encapsulate the semiconductor carrier 3/integrated circuit 1, the mold compound material 25 being viscous during deposition so as to flow into the trenches 21 and further trenches, and the mold compound material 25 hardening after deposition, thereby providing a form closure between the portion of the mold compound material 25 that flowed into the trenches 21 and further trenches and the passivation layer structure 13.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. An integrated circuit, comprising:
a semiconductor carrier comprising an electrically conductive structure on an upper surface thereof;
a passivation layer structure disposed above the upper surface of the semiconductor carrier;
a trench in the passivation layer structure; and
a cover layer on the passivation layer structure, wherein a portion of the cover layer is placed into the trench, thereby providing a form closure between the portion of the cover layer placed into the trench and the passivation layer structure, wherein the trench does not expose the electrically conductive structure on the semiconductor carrier.

2. The integrated circuit of claim 1, further comprising at least one further trench in the passivation layer structure exposing the electrically conductive structure on the upper surface of the semiconductor carrier.

3. The integrated circuit of claim 2, wherein the electrically conductive structure on the upper surface of the semiconductor carrier comprises at least one of an electrically conductive contact and a fuse respectively formed on the upper surface of the semiconductor carrier.

4. The integrated circuit of claim 1,
wherein the cover layer comprises an adhesive material; and
wherein the cover layer is attached to the semiconductor carrier.

5. The integrated circuit of claim 4, wherein the trench in the passivation layer structure is configured such that it has an effect on flow behavior of the adhesive material disposed on an upper surface of the passivation layer structure.

6. The integrated circuit of claim 1,
wherein the cover layer comprises a mold compound material; and
wherein the mold compound material encloses the integrated circuit.

7. The integrated circuit of claim 6, wherein the trench in the passivation layer structure is configured such that it has an effect on flow behavior of the mold compound material disposed on an upper surface of the passivation layer structure.

8. The integrated circuit of claim 1, wherein the trench in the passivation layer structure forms a blind hole in the passivation layer structure.

9. The integrated circuit of claim 1, wherein the passivation layer structure comprises a first passivation layer disposed above the upper surface of the semiconductor carrier and a second passivation layer disposed above the first passivation layer.

10. The integrated circuit of claim 9, wherein the trench in the passivation layer structure forms a blind hole in the first passivation layer or in the second passivation layer.

11. The integrated circuit of claim 1, wherein the trench comprises a lithographic trench.

12. An integrated circuit, comprising:
a semiconductor carrier comprising at least one electrically active region on an upper surface thereof;
a passivation layer structure disposed above the upper surface of the semiconductor carrier; and
at least one trench in the passivation layer structure over the upper surface of the semiconductor carrier, wherein at least a portion of an upper surface of the passivation layer structure is selectively roughened.

13. The integrated circuit of claim 12, wherein at least the portion of the upper surface of the passivation layer structure is selectively etched.

14. The integrated circuit of claim 12, wherein at least the portion of the upper surface of the passivation layer structure is mechanically roughened.

15. A memory module, comprising:
a plurality of integrated circuits, wherein at least one integrated circuit comprises:
a semiconductor carrier comprising an electrically conductive structure on an upper surface thereof;
a passivation layer structure disposed above the upper surface of the semiconductor carrier;
a trench in the passivation layer;
a cover layer on the passivation layer, wherein a portion of the cover layer is placed into the trench, thereby providing a form closure between the portion of the cover layer placed into the trench and the cover layer, wherein the trench does not expose the electrically conductive structure on the semiconductor carrier.

16. An integrated circuit, comprising:
a semiconductor carrier comprising at least one electrically inactive region on an upper surface thereof;
a passivation layer structure disposed above the upper surface of the semiconductor carrier; and
at least one lithographic trench in the passivation layer structure above the at least one electrically inactive region on the upper surface of the semiconductor carrier.

17. The integrated circuit of claim 16, wherein the semiconductor carrier comprises at least one electrically active region on the upper surface thereof, the integrated circuit further comprising:
at least one further trench in the passivation layer structure exposing the at least one electrically active region on the upper surface of the semiconductor carrier.

18. The integrated circuit of claim 17, wherein the at least one electrically active region on the upper surface of the semiconductor carrier comprises at least one of an electrically conductive contact and/or a fuse formed on the upper surface of the semiconductor carrier.

19. The integrated circuit of claim 18, wherein the at least one electrically active region comprises an electrically conductive contact, the integrated circuit further comprising:
electrically conductive contacting material disposed above and in electrical contact with the electrically conductive contact.

20. The integrated circuit of claim 16, further comprising an adhesive formed on an upper surface of the passivation layer structure.

21. The integrated circuit of claim 20, further comprising a mold compound disposed above the adhesive.

22. The integrated circuit of claim 21, wherein the at least one lithographic trench in the passivation layer structure is configured such that it has an effect on adhesion of the mold compound and the passivation layer structure.

23. The integrated circuit of claim 16, wherein the at least one lithographic trench in the passivation layer structure is configured such that it has an effect on a warpage behavior of the semiconductor carrier.

24. The integrated circuit of claim 19, wherein the at least one lithographic trench in the passivation layer structure is configured such that it has an effect on a mechanical stability of the connection between the electrically conductive contacting material and the electrically conductive contact.

25. The integrated circuit of claim 20, wherein the at least one lithographic trench in the passivation layer structure is configured such that it has an effect on flow behavior of the adhesive formed on the upper surface of the passivation layer structure.
